(19) United States
(12) Patent Application Publication
(10) Pub. No.: US 2026/0364817 A1
(43) Pub. Date: Nov. 19, 2026

(54) Wafer Carrying Device, Wafer Processing Device, and Control Method for Wafer Processing Device

(71) Applicant: Ningbo Xinfeng Precision Technology Co., Ltd, Yuyao City (CN)

(72) Inventors: Xianjin WAN, Yuyao City (CN); Zhiyong SUO, Yuyao City (CN); Song ZHU, Yuyao City (CN); Baohong QIN, Yuyao City (CN); Xingliang WEI, Yuyao City (CN); Taiyi XIONG, Yuyao City (CN)

(21) Appl. No.: 19/674,275

(22) Filed: May 12, 2026

(30) Foreign Application Priority Data
May 14, 2025 (CN) 202510619524.7

(51) Int. Cl. B25J 11/00; B24B 9/06; B25J 15/06; H10P 72/00; H10P 72/78

(52) U.S. Cl. CPC B25J 11/0095; B24B 9/065; B25J 15/0683; H10P 72/0428; H10P 72/78

(57) ABSTRACT

Provided are a wafer carrying device, a wafer processing device, and a control method for a wafer processing device. The wafer carrying device includes a carrying body and a vacuum adsorption structure. The carrying body is ring-shaped and has a central through hole. The carrying body is rotatable about the axis of the carrying body. The vacuum adsorption structure is recessed from the upper surface of the carrying body and disposed along the circumferential direction of the carrying body, and the vacuum adsorption structure is configured to perform vacuum adsorption on the edge of a wafer.

### CROSS-REFERENCE TO RELATED APPLICATION(S)

This application claims priority of a Chinese Patent Application filed with China National Intellectual Property Administration (CNIPA) on May 14, 2025, with application No. 202510619524.7, the disclosure of which is incorporated herein by reference in its entirety.

### TECHNICAL FIELD

The present disclosure relates to the technical field of wafer processing and, in particular, to a wafer carrying device, a wafer processing device, and a control method for a wafer processing device.

### BACKGROUND

A 3D stacked chip is a three-dimensional structure formed by vertically stacking multiple chips together through packaging layers, which can significantly reduce the communication distance between chips, increase the data transmission speed, and reduce power consumption. Therefore, 3D stacked chips have broad application prospects in fields such as artificial intelligence, big data, and new energy. The core of 3D stacked chip technology is to thin the thickness of wafers to several microns while maintaining a high degree of flatness, so as to achieve positioning, stacking, and interconnection of chips. As the number of staked wafers increases, the wafers may not be tightly bonded due to an uneven edge of the wafers, and cracks or fragments may easily occur during a subsequent grinding and thinning process of the wafers, seriously affecting the quality and yield of the product. To avoid the preceding situation, the edge of one of two to-be-stacked wafers is trimmed before the two wafers are bonded.

During the trimming of the edge of the wafer, the wafer is adsorbed on a rotatable wafer carrier stage. Grinding is performed on the wafer along the edge of the wafer through a grinding wheel driven by a rotating shaft located on a side of the wafer carrier stage. A recess is provided in the middle of the wafer carrier stage, and a lifting mechanism that can drive the wafer to move up and down is disposed in the recess. A suction nozzle is disposed on the upper surface of the wafer carrier stage along the circumferential direction of the recess, and the suction nozzle is connected to an external vacuum pump. When the wafer is placed on the suction nozzle, the suction nozzle can vacuum adsorb the wafer.

Grinding wheels are available in different thicknesses. During the grinding of the wafer, the grinding wheel may need to be replaced. When a thin grinding wheel is replaced with a thick grinding wheel, and the wafer is ground by the thick grinding wheel, the edge of the wafer is prone to curl because the thin surface of the edge of the wafer has a larger width and insufficient strength. When a thick grinding wheel is replaced with a thin grinding wheel, a portion of the wafer corresponding to the recess of the wafer carrier stage is suspended due to a relatively large diameter of the recess in the middle of the wafer carrier stage, and the wafer is prone to breakage due to an excessive local pressure when the thin grinding wheel grinds the suspended portion of the wafer.

Therefore, when a grinding wheel of a different specification is replaced, it is necessary to adaptively replace a wafer carrier stage with a corresponding recess diameter.

However, the replacement of the corresponding carrier stage along with the replacement of the grinding wheel may lead to a series of operations such as disassembly, reassembly, and parameter readjustment and setting, which are equivalent to reinstallation and recommissioning of the device, significantly reducing working efficiency.

Therefore, there is an urgent need for a wafer carrying device, a wafer processing device, and a control method for a wafer processing device to solve the preceding problems.

### SUMMARY

An object of the present disclosure is to provide a wafer carrying device, a wafer processing device, and a control method for a wafer processing device. During the processing of a wafer, when a thin grinding wheel is replaced with a thick grinding wheel, or when a thick grinding wheel is replaced with a thin grinding wheel, it is unnecessary to replace the wafer carrying device, thereby avoiding adverse effects on wafer processing efficiency and wafer processing quality.

To achieve this object, the present disclosure adopts the technical solutions described below.

A wafer carrying device includes a carrying body and a vacuum adsorption structure.

The carrying body is ring-shaped and has a central through hole. The carrying body is rotatable about the axis of the carrying body.

The vacuum adsorption structure is recessed from the upper surface of the carrying body and disposed along the circumferential direction of the carrying body, and the vacuum adsorption structure is configured to perform vacuum adsorption on the edge of a wafer.

In one or more embodiments, the vacuum adsorption structure includes an air hole, an annular channel that communicates with the air hole is provided in the carrying body, and the annular channel is configured to communicate with a vacuum pump.

In one or more embodiments, the vacuum adsorption structure includes multiple air holes, and the multiple air holes are sequentially arranged at intervals along the circumferential direction of the carrying body.

In one or more embodiments, along the circumferential direction of the carrying body, two adjacent air holes are misaligned along the radial direction of the carrying body.

In one or more embodiments, the air hole has a circular, elliptical, or polygonal shape.

In one or more embodiments, the vacuum adsorption structure is a continuous groove structure.

In one or more embodiments, the groove structure includes multiple sub-grooves sequentially connected along the circumferential direction of the carrying body, and a sub-groove has an arc shape or a sawtooth shape.

In one or more embodiments, the sub-groove has the sawtooth shape with rectangular teeth or triangular teeth.

In one or more embodiments, the wafer carrying device further includes a lifting mechanism, and an output end of the lifting mechanism is disposed in the through hole and is movable up and down relative to the carrying body.

A wafer processing device is further provided and includes a grinding wheel and the preceding wafer carrying device. The grinding wheel is rotatable about the axis of the grinding wheel to process a wafer on the wafer carrying device.

A control method for a wafer processing device is further provided and is used for controlling the preceding wafer processing device and includes the following steps.

In S1, a to-be-processed wafer is placed on the upper surface of the carrying body of the wafer carrying device.

In S2, a vacuum pump is controlled to evacuate the vacuum adsorption structure so that the wafer is vacuum-adsorbed on the upper surface of the carrying body.

In S3, the grinding wheel is controlled to rotate about the axis of the grinding wheel, and the carrying body is simultaneously controlled to rotate about the axis of the carrying body until the grinding wheel completes grinding of the wafer.

The present disclosure has the beneficial effects described below.

When the wafer carrying device provided in the present disclosure carries the wafer, the wafer is placed on the upper surface of the carrying body, and the vacuum adsorption structure is caused to communicate with an external vacuum pump. The vacuum pump is configured to evacuate the vacuum adsorption structure, thereby vacuum adsorbing the wafer on the upper surface of the carrying body. Since the vacuum adsorption structure is disposed along the circumferential direction of the carrying body, the vacuum adsorption structure can perform vacuum adsorption on the circumferential edge of the wafer, thereby preventing the edge of the wafer from curling after a thin grinding wheel is replaced with a thick grinding wheel during the grinding of the wafer.

During design of the wafer carrying device, the diameter of the through hole in the middle of the carrying body may be designed to be smaller than the size of a recess in the middle of a wafer carrier stage in the related art so that the carrying body can provide as much support as possible to a portion of the wafer close to the center of the wafer. When the thick grinding wheel is replaced with the thin grinding wheel during the grinding process, local pressure borne by the wafer increases when the thin grinding wheel acts on the wafer. However, the portion of the wafer aligned with the through hole does not break because the carrying body provides as much support as possible to the portion of the wafer close to the center.

In this manner, adaptive replacement of the wafer carrier stage when the grinding wheel is replaced in the related art can be avoided, and readjustment of relevant parameters is also unnecessary, thereby improving the wafer processing efficiency.

The wafer processing device and the control method for the wafer processing device provided by the present disclosure can ensure the wafer processing quality and the wafer processing efficiency.

### BRIEF DESCRIPTION OF DRAWINGS

To illustrate technical solutions in embodiments of the present disclosure more clearly, drawings used in the description of the embodiments of the present disclosure are briefly described below. Apparently, the drawings described below illustrate only part of the embodiments of the present disclosure, and those of ordinary skill in the art may obtain other drawings based on the content of the embodiments of the present disclosure and the drawings on the premise that no creative work is done.

FIG. 1 is a structural view of a wafer processing device according to embodiment one of the present disclosure.

FIG. 2 is a schematic view of a first form of a vacuum adsorption structure in a wafer carrying device according to embodiment one of the present disclosure.

FIG. 3 is a schematic view of a second form of a vacuum adsorption structure in a wafer carrying device according to embodiment one of the present disclosure.

FIG. 4 is a schematic view of a third form of a vacuum adsorption structure in a wafer carrying device according to embodiment one of the present disclosure.

FIG. 5 is a schematic view of a fourth form of a vacuum adsorption structure in a wafer carrying device according to embodiment one of the present disclosure.

FIG. 6 is a schematic view of a fifth form of a vacuum adsorption structure in a wafer carrying device according to embodiment one of the present disclosure.

FIG. 7 is a schematic view of a sixth form of a vacuum adsorption structure in a wafer carrying device according to embodiment one of the present disclosure.

FIG. 8 is a schematic view of a seventh form of a vacuum adsorption structure in a wafer carrying device according to embodiment one of the present disclosure.

FIG. 9 is a cross-sectional schematic diagram of the wafer carrying device according to embodiment one of the present disclosure.

FIG. 10 is a flowchart of a control method for a wafer processing device according to embodiment two of the present disclosure.

Reference list:
10 grinding wheel
20 spindle
1 carrying body
2 vacuum adsorption structure
21 air hole
3 base
4 Annular channel

### DETAILED DESCRIPTION

The present disclosure is further described below in detail in conjunction with the drawings and embodiments. It is to be understood that the embodiments described herein are intended to explain the present disclosure and not to limit the present disclosure. Additionally, it is to be noted that for convenience of description, only part, not all, of the structures related to the present disclosure are illustrated in the drawings.

In the description of the present disclosure, the terms "joined", "connected", and "fixed" are to be understood in a broad sense unless otherwise expressly specified and limited. For example, the term "connected" may refer to "fixedly connected", "detachably connected", or "integrated", may refer to "mechanically connected" or "electrically connected", or may refer to "connected directly", "connected indirectly through an intermediary", "connected inside two elements", or "an interaction relationship between two elements". For those of ordinary skill in the art, specific meanings of the preceding terms in the present disclosure may be understood based on specific situations.

In the present disclosure, unless otherwise expressly specified and limited, when a first feature is described as "on" or "under" a second feature, the first feature and the second feature may be in direct contact or be in contact via another feature between the two features instead of being in direct contact. Moreover, when the first feature is described as "on", "above", or "over" the second feature, the first feature is right on, above, or over the second feature, the first feature is obliquely on, above, or over the second feature, or the first feature is simply at a higher level than the second feature. When the first feature is described as "under", "below", or "underneath" the second feature, the first feature is right under, below, or underneath the second feature, the first feature is obliquely under, below, or underneath the second feature, or the first feature is simply at a lower level than the second feature.

In the description of this embodiment, orientations or position relations indicated by terms such as "on", "under", "left", and "right" are based on the drawings. These orientations or position relations are intended only to facilitate description and simplify operations and not to indicate or imply that a device or element referred to must have such specific orientations or must be configured or operated in such specific orientations. Thus, these orientations or position relations are not to be construed as limiting the present disclosure. Additionally, the terms "first" and "second" are only used for distinguishing between descriptions and have no special meanings.

### Embodiment one

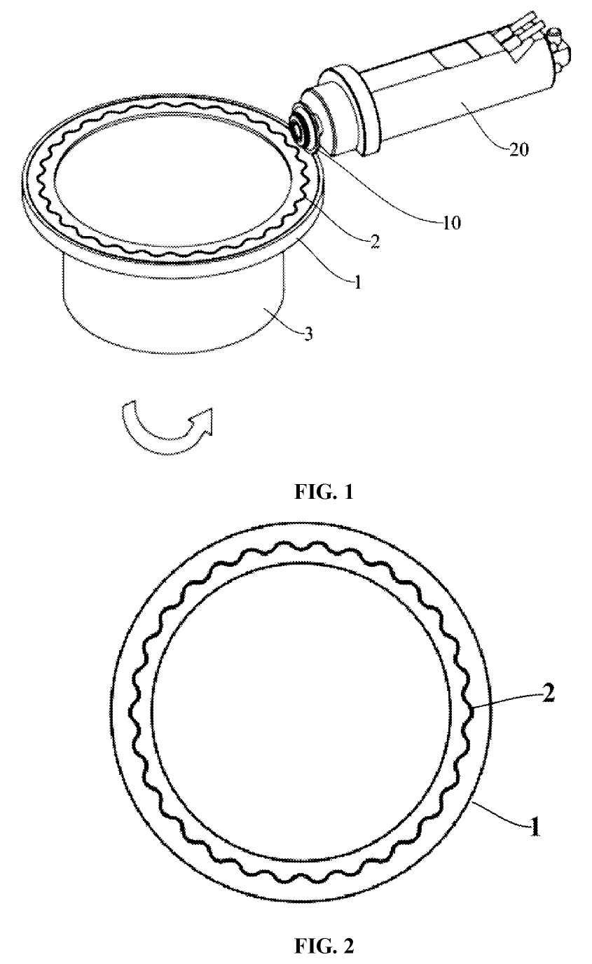

Referring to FIG. 1, this embodiment provides a wafer processing device. The wafer processing device includes a grinding wheel 10 and a wafer carrying device. The wafer carrying device is configured to carry a wafer. The grinding wheel 10 is rotatable about the axis of the grinding wheel 10 to process a wafer on the wafer carrying device.

Further, the wafer processing device further includes a spindle 20. The grinding wheel 10 is fixedly disposed at an output end of the spindle 20. The spindle 20 rotates about the axis of the spindle 20, thereby driving the grinding wheel 10 to rotate.

Referring to FIG. 1, specifically, the wafer carrying device in this embodiment includes a carrying body 1 and a vacuum adsorption structure 2.

The carrying body 1 is ring-shaped and has a central through hole. The carrying body 1 is rotatable about the axis of the carrying body 1.

The vacuum adsorption structure 2 is recessed from the upper surface of the carrying body 1 and disposed along the circumferential direction of the carrying body 1. The vacuum adsorption structure 2 is configured to perform vacuum adsorption on an edge of the wafer.

When the wafer carrying device provided in this embodiment carries the wafer, the wafer is placed on the upper surface of the carrying body 1, and the vacuum adsorption structure 2 is caused to communicate with an external vacuum pump. The vacuum pump is configured to evacuate the vacuum adsorption structure 2, thereby vacuum adsorbing the wafer on the upper surface of the carrying body 1. Since the vacuum adsorption structure 2 is disposed along the circumferential direction of the carrying body 1, the vacuum adsorption structure 2 can perform vacuum adsorption on the circumferential edge of the wafer, thereby preventing the edge of the wafer from curling after a thin grinding wheel is replaced with a thick grinding wheel during grinding of the wafer. In this manner, adaptive replacement of a wafer carrier stage when the grinding wheel is replaced in the related art can be avoided, and readjustment of relevant parameters is also unnecessary, thereby improving wafer processing efficiency and ensuring wafer processing quality.

Specifically, during design of the wafer carrying device, the through hole in the middle of the carrying body 1 may be designed to be as small as possible so that the carrying body 1 can provide as much support as possible to a portion of the wafer close to the center of the wafer. When the thick grinding wheel is replaced with the thin grinding wheel during the grinding process, local pressure borne by the wafer increases when the thin grinding wheel acts on the wafer. However, the portion of the wafer aligned with the through hole does not break because the carrying body 1 provides as much support as possible to the portion of the wafer close to the center.

For example, the thickness of the grinding wheel 10 includes 5 mm and 3 mm. When the grinding wheel 10 with a thickness of 3 mm is used for processing the wafer, the local pressure borne by the wafer is relatively large when the grinding wheel 10 acts on the wafer. However, the carrying body 1 provides as much support as possible to the portion of the wafer close to the center, so the portion of the wafer aligned with the through hole is not broken. When the grinding wheel 10 with a thickness of 3 mm is replaced with a grinding wheel 10 with a thickness of 5 mm, the vacuum adsorption structure 2 can perform vacuum adsorption on the circumferential edge of the wafer because the vacuum adsorption structure 2 is disposed along the circumferential direction of the carrying body 1. Therefore, although the wafer is further thinned by the grinding wheel 10 in this case, the edge of the wafer does not curl.

It is to be understood that the upper end of the vacuum adsorption structure 2 adsorbs the wafer, and the lower end of the vacuum adsorption structure 2 communicates with the external vacuum pump.

Furthermore, the wafer carrying device further includes a lifting mechanism. An output end of the lifting mechanism is disposed in the through hole and is movable up and down relative to the carrying body 1.

Specifically, the wafer carrying device further includes a base 3. The base 3 is a hollow cylinder. The lifting mechanism includes a lifting driving member and a lifting rod. The lifting driving member is disposed in the hollow cylinder. The lifting rod is the output end of the lifting mechanism. The lower end of the lifting rod is connected to an output end of the lifting driving member. The upper end of the lifting rod is movable up and down relative to the through hole of the carrying body 1.

In one or more embodiments, the lifting driving member may be an electric motor or a cylinder.

When the wafer carrying device carries the wafer, the vacuum adsorption structure 2 communicates with the external vacuum pump, and the vacuum adsorption structure 2 is evacuated by the vacuum pump, thereby vacuum adsorbing the wafer on the upper surface of the carrying body 1. In this case, the lifting rod is at the lowest point, and the upper end of the lifting rod is not higher than the upper surface of the carrying body 1 so that the upper end of the lifting rod can be prevented from interfering with the placement of the wafer. In one or more embodiments, the upper end of the lifting rod may be lower than the upper surface of the carrying body 1 in this case.

When the grinding of the wafer is completed, and the wafer needs to be transferred, the vacuum adsorption of the wafer by the vacuum adsorption structure 2 is released, and then the lifting rod is controlled to move up until the lifting rod pushes the wafer up from the upper surface of the carrying body 1. Thus, a certain distance exists between the wafer and the upper surface of the carrying body 1, making it convenient for a robotic arm to pick up the wafer.

Referring to FIGS. 2 and 4, in some embodiments, the vacuum adsorption structure 2 is a continuous groove structure.

The vacuum adsorption structure 2 is the continuous groove structure so that continuous adsorption points can be formed for the edge of the wafer in the circumferential direction, thereby fully preventing the edge of the wafer from curling after the thin grinding wheel is replaced with the thick grinding wheel during the grinding of the wafer.

Further, in one or more embodiments, the vacuum adsorption structure 2 may be an annular groove.

Alternatively, the groove structure includes multiple sub-grooves sequentially connected along the circumferential direction of the carrying body 1, and a sub-groove has an arc shape or a sawtooth shape.

The groove structure includes the multiple sub-grooves sequentially connected along the circumferential direction of the carrying body 1 so that it can be ensured that a vacuum adsorption point exists at each portion of the edge of the wafer in the circumferential direction, thereby fully preventing the edge of the wafer from curling.

The sub-groove has the arc shape or the sawtooth shape. With this configuration, the distances from the adsorption points on the edge of the wafer to the center of the wafer do not remain consistent. Some adsorption points are farther from the center of the wafer, and the other adsorption points are closer to the center of the wafer. The adsorption points closer to the center of the wafer can further prevent the edge of the wafer from curling.

In one or more embodiments, referring to FIG. 2, the groove structure includes the multiple sub-grooves sequentially connected along the circumferential direction of the carrying body 1, and the sub-groove has the arc shape.

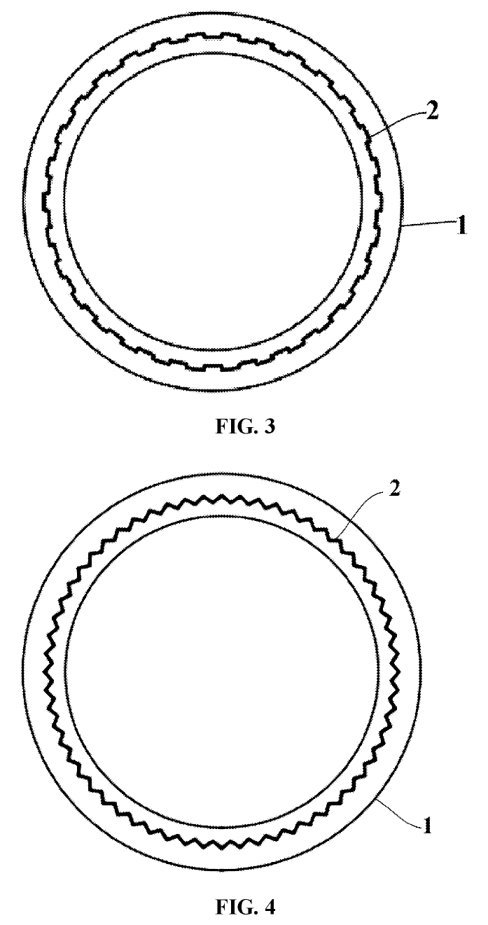

Further, referring to FIGS. 3 and 4, in one or more embodiments, the sub-groove has the sawtooth shape with rectangular teeth or triangular teeth.

It is to be understood that when the vacuum adsorption structure 2 is the continuous groove structure, a connecting channel that communicates with the lower end of the vacuum adsorption structure 2 is provided in the carrying body 1. The connecting channel is a columnar channel or an annular channel. The upper end of the connecting channel communicates with the lower end of the vacuum adsorption structure 2, and the lower end of the connecting channel communicates with the vacuum pump.

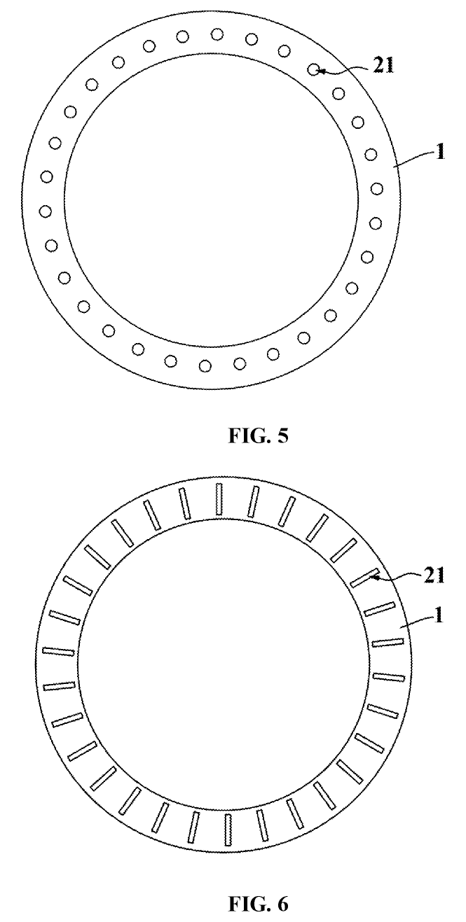

Further, referring to FIGS. 5-8, in some embodiments, the vacuum adsorption structure 2 includes an air hole 21.

As shown in FIG. 9, the annular channel 4 that communicates with the air hole 21 is provided in the carrying body 1, and the annular channel 4 is configured to communicate with the vacuum pump. The vacuum pump evacuates the annular channel 4 so that a vacuum can also be formed in the air hole 21, enabling the wafer to be stably adsorbed on the upper surface of the carrying body 1.

Specifically, the vacuum adsorption structure 2 includes multiple air holes 21, and the multiple air holes 21 are sequentially arranged at intervals along the circumferential direction of the carrying body 1.

The lower end of each air hole 21 communicates with the annular channel 4.

The multiple air holes 21 are sequentially arranged at intervals along the circumferential direction of the carrying body 1, which can form multi-point adsorption to the wafer along the circumferential direction of the edge of the wafer, thereby fully preventing the edge of the wafer from curling and avoiding adverse effects on the wafer processing quality.

In one or more embodiments, referring to FIGS. 5-7, along the circumferential direction of the carrying body 1, the multiple air holes 21 are distributed at intervals annularly.

In one or more embodiments, the air hole 21 has a circular, elliptical, or polygonal shape.

For example, referring to FIG. 5, the air hole 21 has the circular shape, and the multiple air holes 21 are distributed at intervals along the circumferential direction of the carrying body 1 in a ring shape. In some embodiments, when the air hole 21 is circular, the carrying body 1 is provided with a side-adsorption vane groove that communicates with the air hole 21 and is located on a side of the air hole 21 facing away from the center of the carrying body 1. The side-adsorption vane groove can perform better adsorption on the edge of the wafer to fully prevent the edge of the wafer from curling due to an excessively thin edge of the wafer.

For example, referring to FIG. 6, the air holes 21 are rectangular, and the multiple air holes 21 are distributed at intervals along the circumferential direction of the carrying body 1 in a ring shape. In this case, the length direction of the air hole 21 extends along the radial direction of the carrying body 1. Such a configuration enables the end of the air hole 21 facing away from the center point of the carrying body 1 to absorb a portion of the wafer closer to the edge, thereby fully preventing the edge of the wafer from curling.

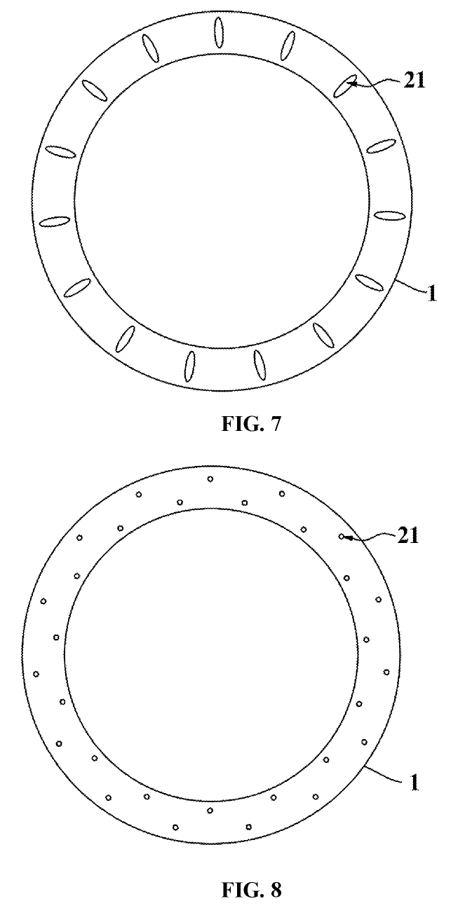

For example, referring to FIG. 7, the air holes 21 are elliptical, and the multiple air holes 21 are distributed at intervals along the circumferential direction of the carrying body 1 in a ring shape. In this case, the long axis of the air hole 21 extends along the radial direction of the carrying body 1. Such a configuration enables the end of the air hole 21 away from the center point of the carrying body 1 to absorb the portion of the wafer closer to the edge, thereby fully preventing the edge of the wafer from curling.

In one or more embodiments, referring to FIG. 8, the multiple air holes 21 are sequentially arranged at intervals along the circumferential direction of the carrying body 1. Along the circumferential direction of the carrying body 1, two adjacent air holes 21 are misaligned along the radial direction of the carrying body 1. Such an arrangement is adopted so that part of the air holes 21 are arranged closer to the inner ring of the carrying body 1, and the other part of the air holes 21 are arranged closer to the outer ring of the carrying body 1. The multiple air holes 21 are sequentially arranged at intervals along the circumferential direction of the carrying body 1, which can form multi-point adsorption to the wafer along the circumferential direction of the edge of the wafer. In addition, the air holes 21 arranged closer to the outer ring of the carrying body 1 can adsorb the portion of the edge of the wafer farther away from the center of the wafer to fully prevent the edge of the wafer from curling.

Specifically, when the vacuum adsorption structure 2 includes the multiple air holes 21, the annular channel 4 that communicates with the lower end of each air hole 21 is provided in the carrying body 1. In addition, the carrying body 1 is further provided with the connecting channel, and the connecting channel is columnar. The upper end of the connecting channel communicates with the lower end of the annular channel 4, and the lower end of the connecting channel communicates with the vacuum pump. In this manner, the vacuum pump can evacuate the air holes 21 so that the wafer can be stably adsorbed on the upper surface of the carrying body 1.

Further, in some embodiments, a positioning annular flange is provided on the upper surface of the carrying body 1 along the circumferential direction of the carrying body 1, and the inner side surface of the positioning annular flange can position the wafer placed on the carrying body 1.

### Embodiment two

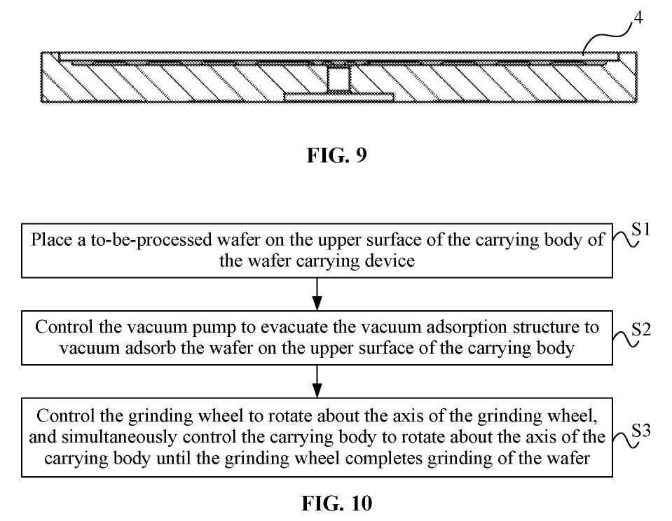

Referring to FIG. 10, this embodiment provides a control method for a wafer processing device. The control method is used for controlling the wafer processing device in embodiment one and includes the following steps.

In S1, a to-be-processed wafer is placed on the upper surface of the carrying body 1 of the wafer carrying device.

In S2, the vacuum pump is controlled to evacuate the vacuum adsorption structure 2 so that the wafer is vacuum adsorbed on the upper surface of the carrying body 1.

In S3, the grinding wheel 10 is controlled to rotate about the axis of the grinding wheel 10, and the carrying body 1 is simultaneously controlled to rotate about the axis of the carrying body 1 until the grinding wheel 10 completes grinding of the wafer.

According to the control method for the wafer processing device provided in this embodiment, the preceding wafer processing device is configured to process the wafer, and the wafer is carried by the wafer carrying device. When the wafer carrying device carries the wafer, the wafer is placed on the upper surface of the carrying body 1, and the vacuum adsorption structure 2 is caused to communicate with an external vacuum pump. The vacuum pump evacuates the vacuum adsorption structure 2, thereby vacuum adsorbing the wafer on the upper surface of the carrying body 1. Since the vacuum adsorption structure 2 is disposed along the circumferential direction of the carrying body 1, the vacuum adsorption structure 2 can perform vacuum adsorption on the circumferential edge of the wafer, thereby preventing the edge of the wafer from curling after a thin grinding wheel is replaced with a thick grinding wheel during the grinding of the wafer. In this manner, adaptive replacement of a wafer carrier stage when the grinding wheel is replaced in the related art can be avoided, and readjustment of relevant parameters is also unnecessary, thereby improving wafer processing efficiency and ensuring wafer processing quality.

More specifically, the control method for the wafer processing device provided in this embodiment specifically includes the following.

The lower end of a lifting rod of a lifting mechanism is controlled to be lower than the upper surface of the carrying body 1.

The to-be-processed wafer is placed on the upper surface of the carrying body 1.

The vacuum pump is started to evacuate the vacuum adsorption structure 2 such that the wafer is vacuum adsorbed on the upper surface of the carrying body 1.

The spindle 20 drives the grinding wheel 10 to rotate about the axis of the grinding wheel 10, and the wafer carrying device is simultaneously controlled to drive the wafer to rotate about the axis of the wafer to complete the grinding of the wafer by the grinding wheel 10.

After the grinding of the wafer is completed, the lifting rod of the lifting mechanism is controlled to move up to push the wafer away from the upper surface of the carrying body 1.

Apparently, the preceding embodiments of the present disclosure are illustrative examples of the present disclosure and are not intended to limit embodiments of the present disclosure. Those of ordinary skill in the art can make various apparent modifications, adaptations, and substitutions without departing from the scope of the present disclosure. All embodiments do not need to be and cannot be exhausted herein. Any modifications, equivalent substitutions, and improvements that are made within the spirit and principle of the present disclosure fall within the scope of the claims of the present disclosure.

What is claimed is:

1. A wafer carrying device, comprising:
a carrying body, wherein the carrying body is ring-shaped and has a central through hole, and the carrying body is rotatable about an axis of the carrying body; and
a vacuum adsorption structure, wherein the vacuum adsorption structure is recessed from an upper surface of the carrying body and disposed along a circumferential direction of the carrying body, and the vacuum adsorption structure is configured to perform vacuum adsorption on an edge of a wafer.

2. The wafer carrying device according to claim 1, wherein the vacuum adsorption structure comprises an air hole, an annular channel that communicates with the air hole is provided in the carrying body, and the annular channel is configured to communicate with a vacuum pump.

3. The wafer carrying device according to claim 2, wherein the vacuum adsorption structure comprises a plurality of air holes, and the plurality of air holes are sequentially arranged at intervals along the circumferential direction of the carrying body.

4. The wafer carrying device according to claim 3, wherein along the circumferential direction of the carrying body, two adjacent air holes among the plurality of air holes are misaligned along a radial direction of the carrying body.

5. The wafer carrying device according to claim 2, wherein the air hole has a circular shape, an elliptical shape, or a polygonal shape.

6. The wafer carrying device according to claim 1, wherein the vacuum adsorption structure is a continuous groove structure.

7. The wafer carrying device according to claim 6, wherein the groove structure comprises a plurality of sub-grooves sequentially connected along the circumferential direction of the carrying body, and a sub-groove of the plurality of sub-grooves has an arc shape or a sawtooth shape.

8. The wafer carrying device according to claim 7, wherein the sub-groove has the sawtooth shape with rectangular teeth or triangular teeth.

9. A wafer processing device, comprising a grinding wheel and a wafer carrying device, wherein the grinding wheel is rotatable about an axis of the grinding wheel to process a wafer on the wafer carrying device; wherein the wafer carrying device comprises a carrying body and a vacuum adsorption structure, wherein the carrying body is ring-shaped and has a central through hole, and the carrying body is rotatable about an axis of the carrying body; and the vacuum adsorption structure is recessed from an upper surface of the carrying body and disposed along a circumferential direction of the carrying body, and the vacuum adsorption structure is configured to perform vacuum adsorption on an edge of a wafer.

10. The wafer processing device according to claim 9, wherein the vacuum adsorption structure comprises an air hole, an annular channel that communicates with the air hole is provided in the carrying body, and the annular channel is configured to communicate with a vacuum pump.

11. The wafer processing device according to claim 10, wherein the vacuum adsorption structure comprises a plurality of air holes, and the plurality of air holes are sequentially arranged at intervals along the circumferential direction of the carrying body.

12. The wafer processing device according to claim 11, wherein along the circumferential direction of the carrying body, two adjacent air holes among the plurality of air holes are misaligned along a radial direction of the carrying body.

13. The wafer processing device according to claim 10, wherein the air hole has a circular shape, an elliptical shape, or a polygonal shape.

14. The wafer processing device according to claim 9, wherein the vacuum adsorption structure is a continuous groove structure.

15. The wafer processing device according to claim 14, wherein the groove structure comprises a plurality of sub-grooves sequentially connected along the circumferential direction of the carrying body, and a sub-groove of the plurality of sub-grooves has an arc shape or a sawtooth shape.

16. The wafer processing device according to claim 15, wherein the sub-groove has the sawtooth shape with rectangular teeth or triangular teeth.

17. A control method for a wafer processing device, wherein the wafer processing device comprises a grinding wheel and a wafer carrying device, the grinding wheel is rotatable about an axis of the grinding wheel to process a wafer on the wafer carrying device, and the wafer carrying device comprises a carrying body and a vacuum adsorption structure, wherein the carrying body is ring-shaped and has a central through hole, and the carrying body is rotatable about an axis of the carrying body; and the vacuum adsorption structure is recessed from an upper surface of the carrying body and disposed along a circumferential direction of the carrying body, and the vacuum adsorption structure is configured to perform vacuum adsorption on an edge of a wafer; and the control method comprises:
placing a to-be-processed wafer on the upper surface of the carrying body of the wafer carrying device;
controlling a vacuum pump to evacuate the vacuum adsorption structure to vacuum adsorb the wafer on the upper surface of the carrying body; and
controlling the grinding wheel to rotate about the axis of the grinding wheel, and simultaneously controlling the carrying body to rotate about the axis of the carrying body until the grinding wheel completes grinding of the wafer.
